(19) United States
(12) Patent Application Publication
(10) Pub. No.: US 2009/0279365 A1
(43) Pub. Date: Nov. 12, 2009

(54) NON-VOLATILE SEMICONDUCTOR MEMORY SYSTEM

(76) Inventor: Tomoharu TANAKA, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/507,524

(22) Filed: Jul. 22, 2009

Related U.S. Application Data
(63) Continuation of application No. 11/043,168, filed on Jan. 27, 2005.

(30) Foreign Application Priority Data
Jan. 28, 2004 (JP) 2004-019626

(51) Int. Cl. G11C 11/34

(52) U.S. Cl. 365/185.33

(57) ABSTRACT

A non-volatile semiconductor memory system includes a first memory block group including a plurality of memory blocks each including a plurality of erasable and programmable non-volatile semiconductor memory cells and a second memory block group including a plurality of memory blocks each including a plurality of erasable and programmable non-volatile semiconductor memory cells. Block addresses of the second memory block group and block addresses of the first memory block group are non-continuous via blank addresses.

### CROSS-REFERENCE TO RELATED APPLICATIONS

This application is a continuation of U.S. application Ser. No. 11/043,168, filed on Jan. 27, 2005, and is based upon and claims the benefit of priority from prior Japanese Patent Application No. 2004-019626, filed Jan. 28, 2004, the entire contents of both of which are incorporated herein by reference.

### BACKGROUND OF THE INVENTION

1. Field of the Invention

The present invention relates to an electrically rewritable non-volatile semiconductor memory system. In particular, the present invention relates to a flash memory system.

2. Description of the Related Art

A flash memory changes the charge of the floating gate of memory cell transistor (erase-write operation) to vary the threshold, and thereby, stores data. For example, a negative threshold value corresponds to data “1” while a positive threshold value corresponds to data “0”.

A memory cell forms a memory array arrayed like a matrix, and is selected according to row address and column address. Thereafter, erase, write and read are carried out with respect to the selected memory cell.

If the entire memory cells included in the memory array do not normally operate, a bad memory cell is replaced with a prepared redundancy memory cell by changing row address and column address. If the redundancy memory cell is not enough, there has been recently known the following method. According to the method, erase/write to the bad memory cell is inhibited on the system level without replacing the bad memory cell. The method is described in the following Document 1, page 34 (13) Invalid blocks (bad blocks), for example.

Document 1: “TENTATIVE TOSHIBA MOS DIGITAL INTEGRATED CIRCUIT SILICON GATE CMOS 2 GBIT (256M×8 BIT/128M×16 BIT) CMOS NAND E²PROM, TOSHIBA, [searched on Jan. 23, 2004], Internet <Hyperlink symbology omitted>

### BRIEF SUMMARY OF THE INVENTION

A semiconductor integrated circuit device according to an aspect of the present invention comprises: a first memory block group including a plurality of memory blocks each including a plurality of erasable and programmable non-volatile semiconductor memory cells; and a second memory block group including a plurality of memory blocks each including a plurality of erasable and programmable non-volatile semiconductor memory cells, block addresses of the second memory block group and block addresses of the first memory block group being non-continuous via blank addresses.

### BRIEF DESCRIPTION OF THE SEVERAL VIEWS OF THE DRAWING

FIG. 1 is a block diagram showing the configuration of a non-volatile semiconductor memory device, that is, a flash memory according to one embodiment of the present invention;

FIG. 2 is a view showing the circuit configuration of a memory cell array 1 shown in FIG. 1;

FIG. 3 is a cross-sectional view showing the cross-sectional structure along the column direction of the memory cell array 1 shown in FIG. 1;

FIG. 4 is a cross-sectional view showing the cross-sectional structure along the row direction of the memory cell array 1 shown in FIG. 1;

FIG. 5 is a cross-sectional view showing the cross-sectional structure along the row direction of the memory cell array 1 shown in FIG. 1;

FIG. 6 is a view showing the configuration of principal parts of a column control circuit 2;

FIG. 7 is a chart showing a relation between data of the flash memory according to one embodiment and the threshold of a memory cell;

FIG. 8 is a block diagram showing the system configuration of a flash memory system according to one embodiment;

FIG. 9 is a waveform chart to explain the read control operation of the flash memory system shown in FIG. 8;

FIG. 10 is a waveform chart to explain the erase control operation of the flash memory system shown in FIG. 8;

FIG. 11 is a waveform chart to explain the write control operation of the flash memory system shown in FIG. 8;

FIG. 12 is a view to explain the block address allocation of the flash memory system shown in FIG. 8;

FIG. 13 is a view showing the number of blocks according to a comparative example;

FIG. 14 is a view showing the number of blocks according to one embodiment;

FIG. 15 is a block diagram showing the configuration of a memory card;

FIG. 16 is a block diagram showing the configuration of another memory card;

FIG. 17 is a plan view showing an IC card;

FIG. 18 is a block diagram showing the configuration of the IC card;

FIG. 19 is a perspective view showing a card holder;

FIG. 20 is a perspective view showing an electronic device;

FIG. 21 is a perspective view showing another electronic device;

FIG. 22 is a block diagram showing the configuration of a portable (mobile) phone terminal;

FIG. 23 is a view showing a digital still camera/video camera;

FIG. 24 is a view showing a television;

FIG. 25 is a view showing an audio/visual apparatus;

FIG. 26 is a view showing an audio apparatus;

FIG. 27 is a view showing a game machine (assistant);

FIG. 28 is a view showing an electronic musical instrument;

FIG. 29 is a view showing a portable (mobile) phone;

FIG. 30 is a view showing a personal computer;

FIG. 31 is a view showing a personal digital assistant;

FIG. 32 is a view showing a voice recorder;

FIG. 33 is a view showing a PC card; and

FIG. 34 is a view showing an electronic book viewer (reader).

### DETAILED DESCRIPTION OF THE INVENTION

Advance in micro-fabrication of non-volatile semiconductor memory is made; on the contrary, a high probability that bad memory cells appear becomes high. For this reason, the number of redundancy memory cells increases. In order to replace the bad memory cell with a redundancy memory cell, an address converter circuit is required. A area of the memory cell is reduced resulting from the micro-fabrication; however, the area of the address converter circuit increases. For this reason, cost merits by the micro-fabrication are not sufficiently obtained.

If the redundancy memory cell is not enough, erase/write to the bad memory cell is inhibited on the system level without replacing the bad memory cell. Even if the foregoing method is employed, the number of the bad memory cells increases, and thereby, the storage capacity increases; as a result, the product value is reduced.

One embodiment of the present invention will be described below with reference to the accompanying drawings. In the following description, the same reference numerals are used to designate the identical parts in all drawings.

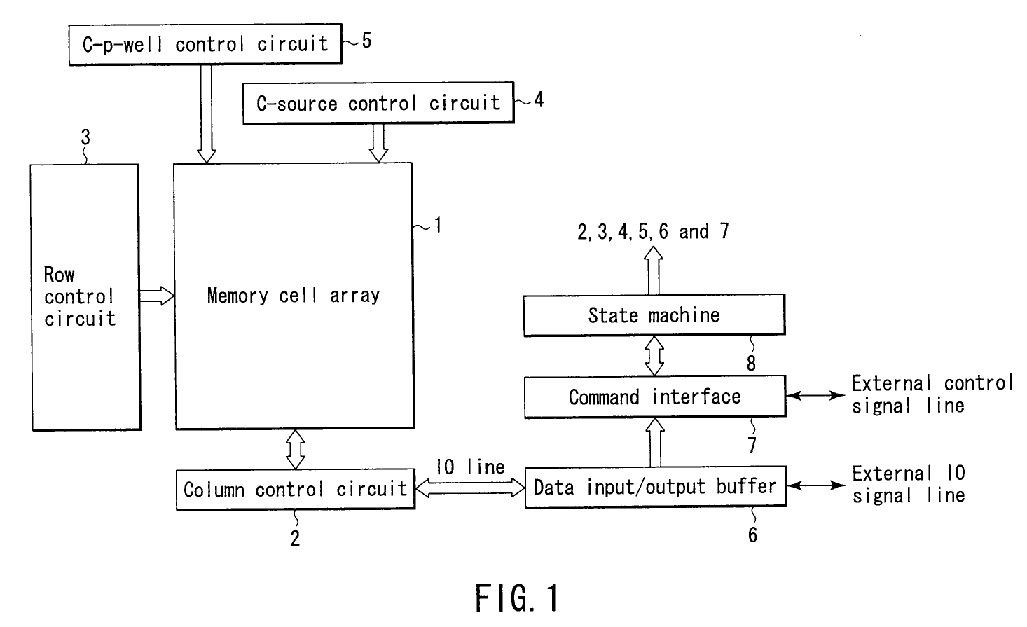

FIG. 1 is a block diagram showing the configuration of a non-volatile semiconductor memory device, that is, a flash memory according to one embodiment of the present invention.

As shown in FIG. 1, a memory cell array 1 has the structure in which flash memory cells are arrayed like a matrix. A column control circuit 2 is arranged adjacent to the memory cell array 1. The column control circuit 2 controls bit lines of the memory cell array 1, and carries out data erase of memory cell, data write to memory cell and data read from memory cell. The flash memory is provided with a row control circuit 3, which selects word lines of the memory cell array 1, and applies voltage required for erase, write and read. In addition, the flash memory is provided a source control circuit 4 and a P-well control circuit 5. The source control circuit 4 controls source lines of the memory cell array 1, and the P-well control circuit 5 controls p-well formed with the memory cell array 1.

The flash memory is provided with a data input/output buffer 6, which is connected to an external host (for example, computer) (not shown) via an I/O line. The data input/output buffer 6 receives write data, outputs read data, and receives address and command data. The buffer 6 sends the received write data to the column control circuit 2 while receiving data read from there. In order to select a memory cell, the buffer 6 sends external address data to column and row control circuits 2 and 3 via a state machine 8. The buffer 6 sends command data from the host to a command interface 7.

When receiving a control signal from the host, the command interface 7 determines whether the data inputted to the data input/output buffer 6 is write data, command data or address data. If the data is command data, the command interface 7 receives it, and thereafter, transfers it to the state machine 8 as a command signal.

The state machine 8 manages the whole of the flash memory. When receiving a command from the host, the state machine 8 controls read, write, erase and data input/output, thereby the state machine 8 manages read, write, erase and data input/output.

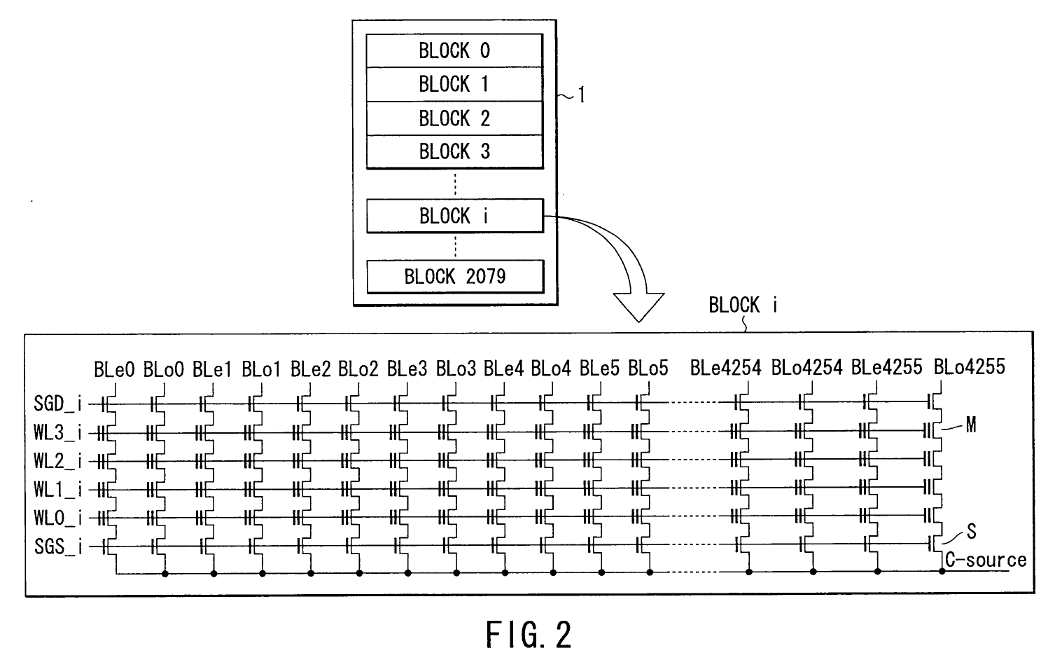

FIG. 2 is a view showing the circuit configuration of the memory cell array 1.

As seen from FIG. 2, the memory cell array 1 is divided into several memory cell blocks BLOCK0 to BLOCK2079. The block is used as the minimum erase unit. Each block BLOCKi is composed of 8512 NAND memory units.

Each NAND memory unit is composed of four memory cells M connected in series. The NAND memory cell unit has one terminal connected to a bit line BL via a select gate S connected to a select gate line SGD. The NAND memory cell unit has the other terminal connected to a common source line C-source via a select gate S connected to a select gate line SGS. Each memory cell is connected to a word line WL. In counting bit lines from 0, even number bit lines BLe and odd number bit lines BLo carry out data write and read independently from each other. Data write and read are simultaneously carried out with respect to 4256 memory cells connected to even number bit lines BLe of 8512 memory cells connected to one word line WL. Each memory cell stores one-bit data; therefore, 4256 memory cells (connected to even number bit lines BLe) form a so-called page. Likewise, 4256 memory cells connected to odd number bit lines BLo form another page. Data write and read are simultaneously carried out with respect to memory cells included in the page.

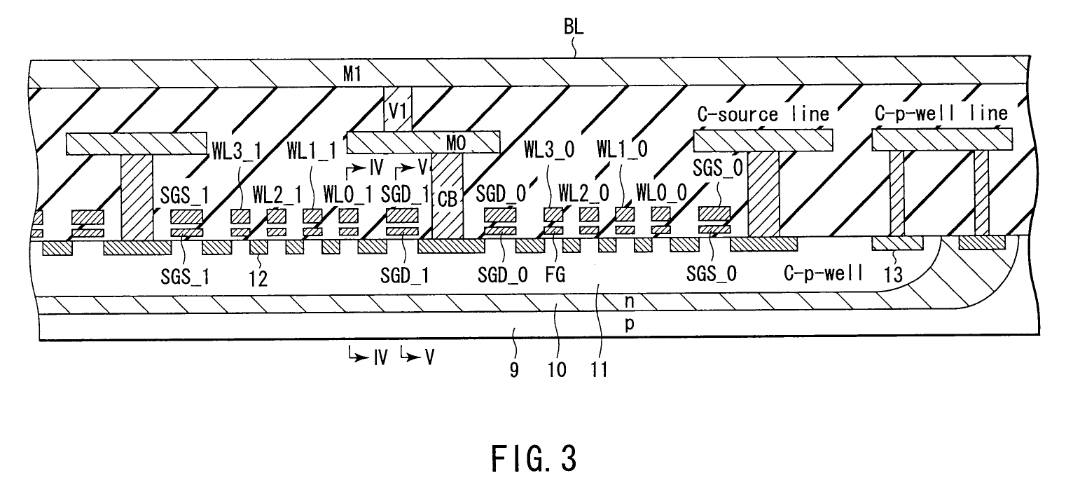

FIG. 3 is a cross-sectional view showing the cross-sectional structure along the column direction of the memory cell array 1.

As illustrated in FIG. 3, an n-well 10 is formed on a p-type substrate 9, and a p-well 11 is formed in the n-well 10. The memory cell M is composed of source/drain formed in an n-type diffusion layer 12 and a control gate functioning as floating gate FG and word line WL. The select gate S is composed of the source/drain formed in the n-type diffusion layer 12 and stacked structural select gate lines SG (SGS, SGD). Word lines and select gate lines SG are connected to the row control circuit 3 so that these lines can be controlled.

One terminal of the NAND memory unit is connected to a first metal interconnection layer M0 via a first contact hole CB. Further, the terminal is connected to a second metal interconnection layer M1 functioning as a bit line BL via a second contact hole V1. The bit line BL is connected to the column control circuit 2. The other terminal of the NAND memory unit is connected to the first metal interconnection layer M0 functioning as a common source line C-source via the first contact hole CB.

The foregoing n-well 10 and p-well 11 have the same potential, and are connected to the P-well control circuit 5 via a well line C-p-well.

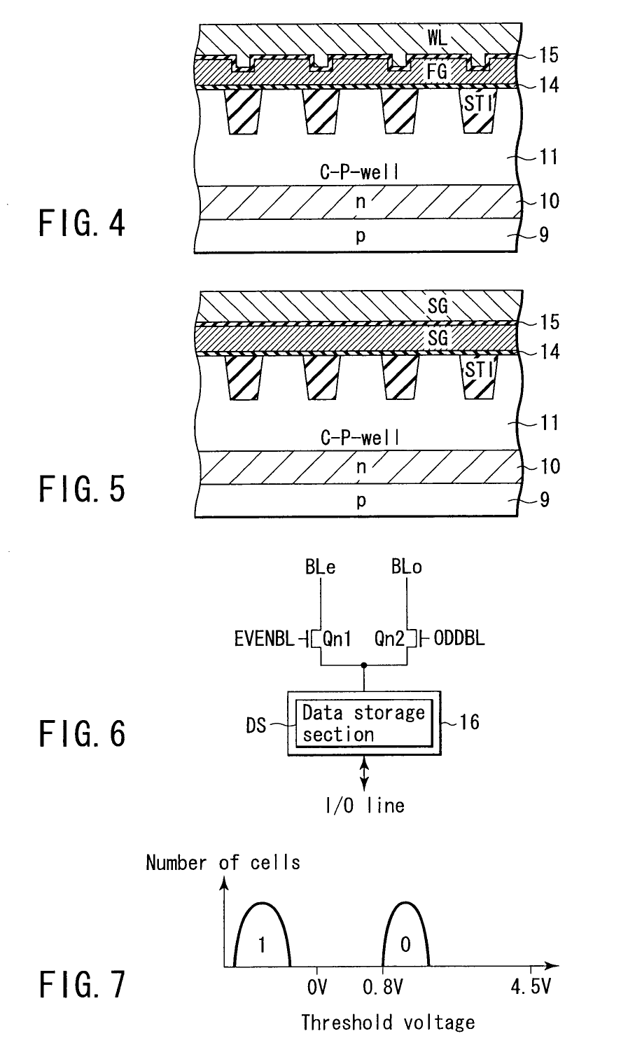

FIG. 4 and FIG. 5 are cross-sectional views showing the cross-sectional structure along the row direction of the memory cell array 1. FIG. 4 shows a cross section taken along the line IV-IV of FIG. 3, and FIG. 4 shows a cross section taken along the line V-V of FIG. 3.

As depicted in FIG. 4, the memory cells M are isolated via an element isolation region STI. The floating gate FG is provided above a channel region via a tunnel oxide film 14. The word line WL is stacked on the floating gate FG via an ONO film 15.

The select gate line SG has the stacked structure as seen from FIG. 5. Top and bottom select gate lines SG are connected to ends of the memory cell array or every the fixed number of bit lines.

FIG. 6 is a view showing the configuration of principal parts of the column control circuit 2. FIG. 6 shows a part for selecting even number bit line BLe or odd number bit line BLo, in particular.

As seen from FIG. 6, a data storage circuit 16 is provided every two lines, that is, even number bit line BLe and odd number bit line BLo having the same column number (e.g., BLe5 and BLo5). When either of these bit lines is selected, the selected bit line is connected to the data storage circuit 16 so that data write or read can be controlled. More specifically, when a signal EVENBL is H is level while a signal ODDBL becomes L level, the even number bit line BLe is selected. Thus, the even number bit line BLe is connected to the data storage circuit 16 via an n-channel MOS transistor Qn1. On the other hand, when the signal EVENBL is L level while the signal ODDBL becomes H level, the odd number bit line BLo is selected. Thus, the odd number bit line BLo is connected to the data storage circuit 16 via an n-channel MOS transistor Qn2. The EVENBL is common to all even number bit lines BLe, and the signal ODDBL is common to all odd number bit lines BLe. A non-select bit line BL is controlled by a circuit (not shown).

The data storage circuit 16 includes a data storage section DS. The data storage section DS is connected with the data input/output buffer 6 via a data input/output line (I/O line), and stores externally inputted write data and read data outputted to the external device.

FIG. 7 is a chart showing a relation between the data of the flash memory according to one embodiment and the threshold of the memory cell M. In FIG. 7, one memory cell M stores one-bit data.

As seen from FIG. 7, the data of the memory cell M is “1” after erase. If the write data to the memory cell M is “0”, the data changes “1” to “0” by write. If the write data is “1”, it is kept unchanged as being “1”. If the threshold is 0 V or less, the data is regarded as “1”. If the threshold is 0 V or more, the data is regarded as “0”.

Table 1 shows each line voltage in erase, write, read write verification.

TABLE 1

| | | | Write | | Write |
|---|---|---|---|---|---|
| | Erase | Write | inhibition | Read | verification |
| BLe | Floating | 0 V | Vdd | H or L | H or L |
| BLo | Floating | Vdd | Vdd | 0 V | 0 V |
| SGD | Floating | Vdd | Vdd | 4.5 V | 4.5 V |
| WL3 | 0 V | 10 V | 10 V | 4.5 V | 4.5 V |
| WL2 | 0 V | Vpgm | Vpgm | 0 V | 0.8 V |
| WL1 | 0 V | 0 V | 0 V | 4.5 V | 4.5 V |
| WL0 | 0 V | 10 V | 10 V | 4.5 V | 4.5 V |
| SGS | Floating | 0 V | 0 V | 4.5 V | 4.5 V |
| C- | Floating | 0 V | 0 V | 0 V | 0 V |
| source | | | | | |
| C-p- | 20 V | 0 V | 0 V | 0 V | 0 V |
| well | | | | | |

According to the Table 1, the case where the word line WL2 and the even number bit line BLe are selected in write and read will be explained.

In erase, the p-well 11 is set as 20 V, and all word lines WL0 of the selected block are set as 0 V. By doing so, electrons is emitted from the floating gate FG of the memory cell M, and thus, the threshold becomes negative; as a result, the state “1” is given. In this case, word lines and bit lines BL in the non-select block are floating; therefore, they become nearly 20 V by capacitance combination with the p-well 11.

Write is carried out in a manner of applying Vpgm of 14 V to 20 V to the selected word line WL2. When the selected bit line BLe is set as 0 V, electrons are injected to the floating gate FG, and thus, the threshold value increases (write). In order to inhibit the increase of the threshold value, the bit line BLe is set as power supply voltage Vdd (˜3 V) (write inhibition).

Read is carried out in a manner of applying read voltage (0 V) to the selected word line WL2. If the threshold value of the memory cell M is less than the read voltage, bit line BLe and common source line C-source are conductive. Thus, the potential of the bit line BLe becomes relatively low level L (“1” read). If the threshold value of the memory cell M is more than the read voltage, bit line BLe and common source line C-source are non-conductive. Thus, the potential of the bit line BLe becomes relatively high level H (“0” read).

The threshold value of the state “0” is set to 0.8 or more V to have 0.8 V read margin with respect to the read voltage 0V. For this reason, if write “0” is made, the write is verified. When detection is made that the threshold value of the memory cell M reaches 0.8 V, write is inhibited to control the threshold value.

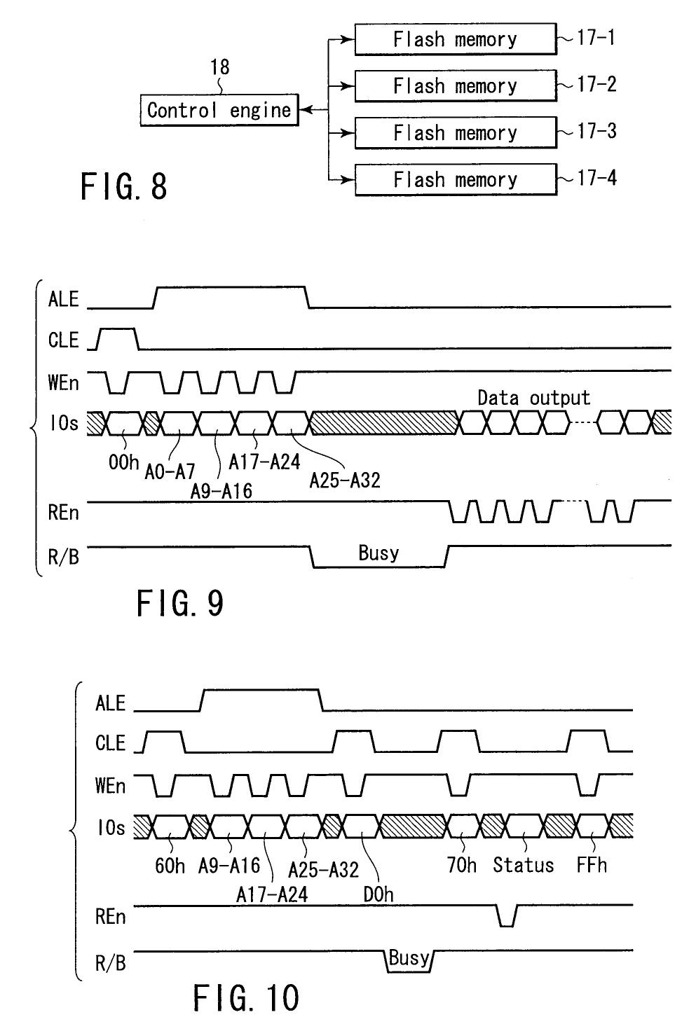

FIG. 8 shows the configuration of a flash memory system using four flash memories 17 shown in FIG. 1 in one embodiment. A control engine 18 controls four flash memories 17-1 to 17-4.

FIG. 9 is a waveform chart showing the read control operation of the flash memory system shown in FIG. 8.

As illustrated in FIG. 9, the control engine 18 issues a read command 00h to the flash memory 17. An address is inputted to select a memory cell. After four-times address inputs (A0-A7, A9-A16, A17-A24, A25-A32), the flash memory automatically becomes a BUSY state. Data is read to the corresponding data storage section DS from the memory cell selected during the BUSY state. The BUSY state is released, and thereafter, the data read to the data storage section DS is outputted to the control engine 18 using a read enable signal as toggle. Incidentally, the address A8 is not shown because the present invention is adapted to actual device specifications. In the actual device, the address A8 is converted using commands. In the following erase and write control operations, the address A8 is not shown resulting from the same reason as above.

FIG. 10 is a waveform chart showing the erase control operation of the flash memory system shown in FIG. 8.

As shown in FIG. 10, the control engine 18 issues an erase address input command 60h to the flash memory 17. An address is inputted to select a memory cell. After three-times address inputs (A9-A16, A17-A24, A25-A32), when an erase command D0h is inputted, the flash memory automatically becomes a BUSY state. Data is erased from the memory cell block selected during the BUSY state. The BUSY state is released, and thereafter, the control engine 18 issues a status read command to confirm whether or not erase is correctly made using a read enable signal as toggle. The control engine 18 issues a reset command FFh, and thereby, the flash memory is reset.

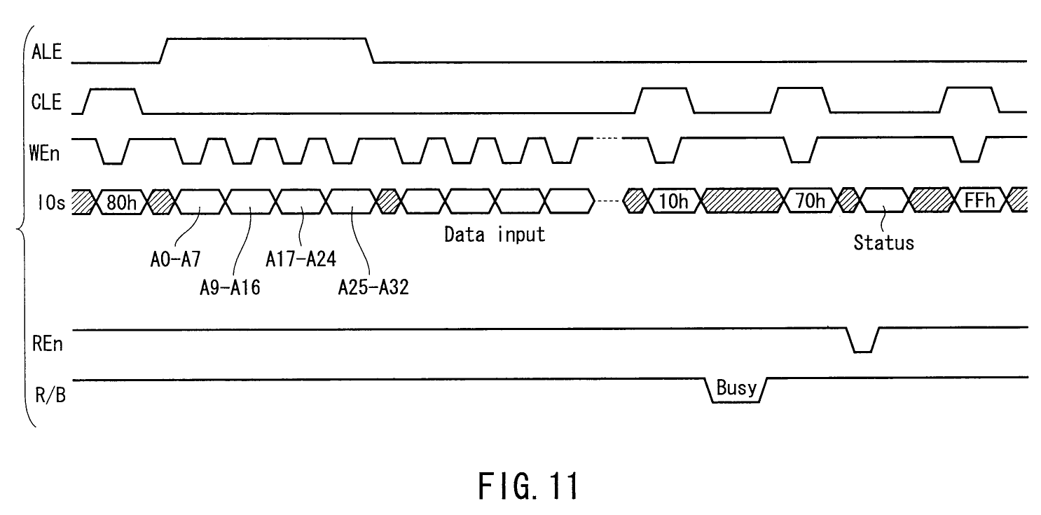

FIG. 11 is a waveform chart showing the write control operation of the flash memory system shown in FIG. 8.

As depicted in FIG. 11, the control engine 18 issues a write address input command 80h to the flash memory 17. An address is inputted to select a page. After four-times address inputs (A0-A7, A9-A16, A17-A24, A25-A32), write data and write command 10h are inputted, the flash memory automatically becomes a BUSY state. The inputted data is written to the page selected during the BUSY state. The BUSY state is released, and thereafter, the control engine 18 issues a status read command to confirm whether or not write is correctly made using the read enable signal as toggle. The control engine 18 issues the reset command FFh, and thereby, the flash memory is reset.

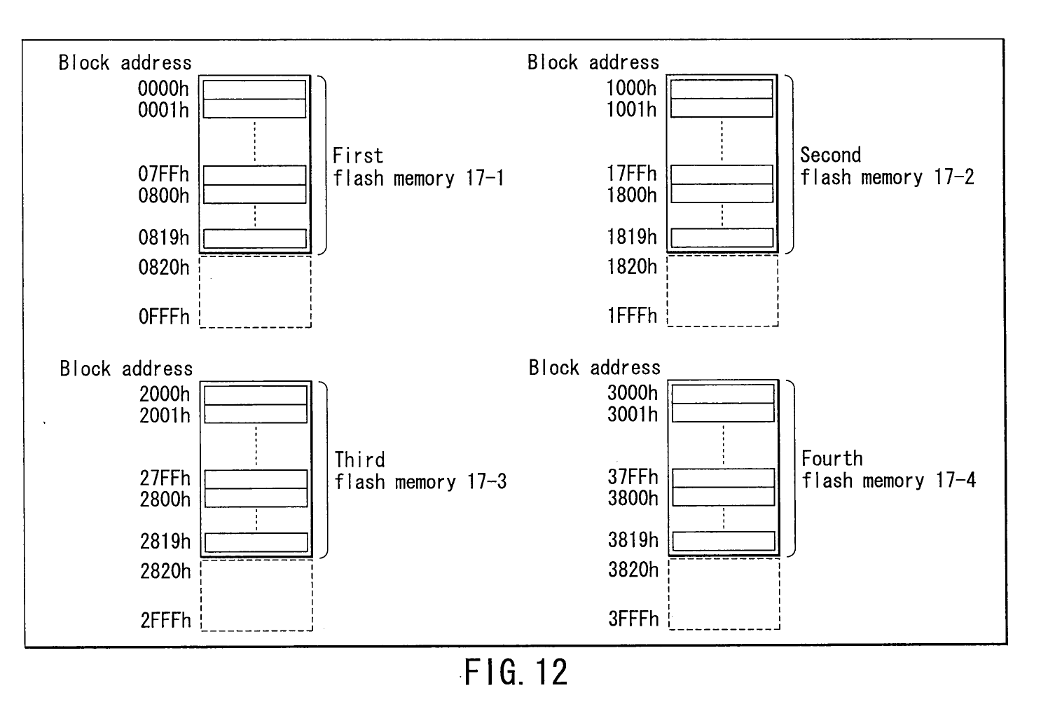

FIG. 12 is a view to explain the block address allocation of the flash memory system shown in FIG. 8.

As seen from FIG. 12, the flash memories 17 (17-1 to 17-4) do not replace bad blocks with redundancy blocks, unlike the conventional semiconductor memory. Block address is allocated to portions corresponding to conventional redundancy blocks so that the external device, that is, the control engine 18 controls these blocks. If there exist bad blocks, the control engine 18 detects the bad blocks, and erase/write with respect to these bad blocks is not carried out (i.e., bad blocks are not used). In the embodiment, 32 redundancy blocks are given with respect to 2048 blocks (=2¹¹). Thus, even if 32 bad blocks occur, storage capacity equivalent to 2048 blocks can be secured. By doing so, the flash memory 17 does not need to have a circuit for replacing bad blocks with redundancy blocks.

Logical block addresses 0000h to 0819h are continuously allocated to 2080 blocks of the first flash memory 17-1. Logical block addresses 1000h to 1819h are continuously allocated to 2080 blocks of the second flash memory 17-2. There exist no allocated block from logical block addresses 0820h to 0FFFh. By doing so, the leading block address of the second flash memory 17-2 is simply expressed. Therefore, this serves to make conversion of external and internal addresses in the flash memory using simple circuit, and in addition to reduce the cost of the flash memory 17.

Likewise, logical block addresses 2000h to 2819h are continuously allocated to 2080 blocks of the third flash memory 17-3. Logical block addresses 3000h to 3819h are continuously allocated to 2080 blocks of the fourth flash memory 17-4.

In the embodiment, one flash memory 17 includes one memory cell array 1. For example, if one flash memory includes four memory cell arrays, block address allocation shown in FIG. 12 is made, and thereby, the same effect as above is obtained. If one flash memory includes two memory cell arrays, a system using two flash memories is employed, and block address allocation shown in FIG. 12 is made. By doing so, the same effect as above is obtained.

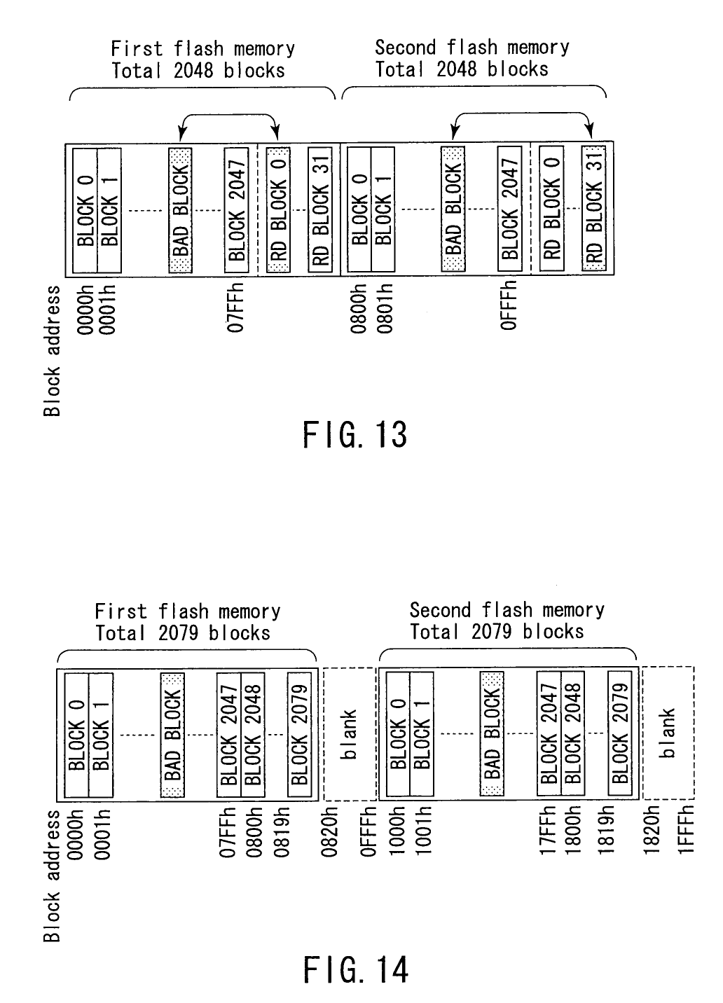

FIG. 13 is a view showing the number of blocks in a comparative example, and FIG. 14 is a view showing the number of blocks in one embodiment. The difference between the comparative example and one embodiment will be explained below. In this case, the total number of blocks is the same. The comparative example is equivalent to a memory with general redundancy circuit.

According to the comparative example, 32 redundancy blocks (RD BLOCK) for replacement are provided with respect to 2048 (=2¹¹) blocks. If a bad block (BAD BLOCK) occurs, it is replaced with one of the redundancy blocks RD BLOCK. Thus, the number of blocks of 2048 or more is not seen from the outside of the flash memory. Usually, the replacement is carried out before product delivery, and it is impossible to replace bad blocks occurring in the market. For example, if three blocks becomes bad after product delivery, the total number of blocks is 2045.

On the contrary, according to the embodiment, 2080 blocks are seen from the outside of the flash memory. Thus, even if one bad block (BAD BLOCK) occurs, 2079 blocks are still supplied. In addition, if three blocks becomes bad after product delivery, 2076 blocks are still supplied.

According to one embodiment, even if the flash memory is formed using the same number of blocks, the memory capacity is made large. In addition, even if many bad blocks occur, the same memory capacity as the conventional case is supplied; therefore, reliability is improved.

More specifically, one embodiment of the present invention provides a non-volatile semiconductor memory system comprising:

an electrically erasable and rewritable non-volatile semiconductor memory cell (M);

a memory block (BLOCK) composed of several memory cells;

a first memory block group (ARRAY) composed of several memory blocks; and

a second memory block group (ARRAY) composed of several memory blocks, memory block address of the first and second memory block groups being non-continuous via a blank memory block address.

The following technical advantages are given.

(1) The first memory block group is composed of at least 2ⁿ (n power of 2) memory blocks and N (N<2ⁿ) memory blocks.

(2) The second memory block group is composed of at least 2ⁿ (n power of 2) memory blocks and N (N<2ⁿ) memory blocks.

(3) The system further includes a control engine 18 controlling each memory block. The control engine 18 detects a bad memory block so that erase and read can not be carried out with respect to the detected bad memory block.

(4) The first and second memory block groups individually have a bit line BL common to each memory block.

(5) The memory block is the minimum erase unit.

As seen from the foregoing description, the circuit built in the non-volatile semiconductor memory is simplified, and thereby, cost merits by micro-fabrication are sufficiently obtained. In addition, it is possible to secure sufficient storage capacity, and thus, to provide a non-volatile semiconductor memory system having high reliability.

The following are descriptions on application examples using the non-volatile semiconductor memory according to one embodiment of the present invention.

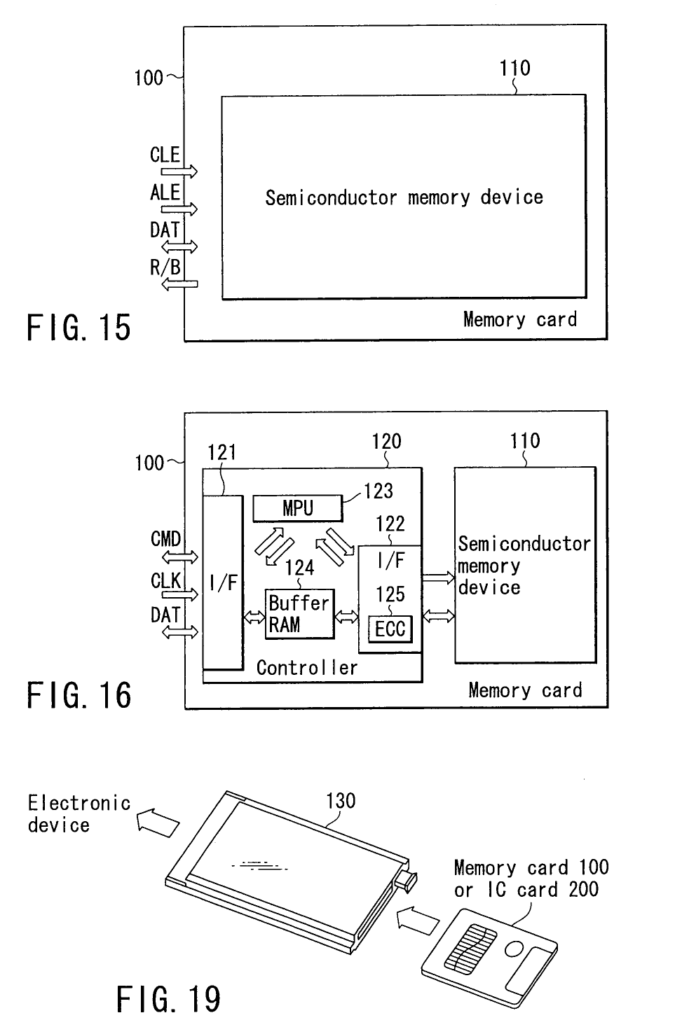

FIG. 15 shows a memory card.

As shown in FIG. 15, a memory card 100 has a non-volatile semiconductor memory device 110 according to one embodiment of the present invention or the modification example. The semiconductor memory device 110 receives predetermined control signal and data from an external device (not shown). The semiconductor memory device 110 outputs predetermined control signal and data to the external device (not shown).

The semiconductor memory device 110 built in the memory card 100 is connected with the following signal lines. One is a signal line (DAT) transferring data, address or command. Another is a command line enable signal line (CLE) indicative that command is transferred to the signal line (DAT). Another is an address line enable signal line (ALE) indicative that address is transferred to the signal line (DAT). Another is a ready/busy signal line (R/B) showing whether or not the semiconductor memory device 110 is operable.

FIG. 16 shows another memory card.

The memory card shown in FIG. 16 differs from the memory card 100 shown in FIG. 15 in the following point. The memory card shown in FIG. 16 is provided with a controller 120, which controls the semiconductor memory device 110, and makes predetermined signal exchange with the external device (not shown). The controller 120 has interfaces (I/F) 121 and 122, microprocessor (MPU) 123, buffer RAM 124, and error checking and correcting section (ECC) 125. More specifically, the interfaces 121 and 122 receive predetermined control signal and data from semiconductor memory device 110 and external device (not shown), or output them to the external device. The microprocessor 123 makes predetermined calculations for converting logical address inputted from the external device into physical address. The buffer RAM 124 temporarily stores data, and the error checking and correcting section 125 generates error correction codes. The memory card 100 is connected with command signal lines (CMD), clock signal line (CLK) and signal line (DAT).

In the memory cards 100 according to the application examples, the number of control signals, the bit width of signal line or the configuration of the controller 120 may be variously modified.

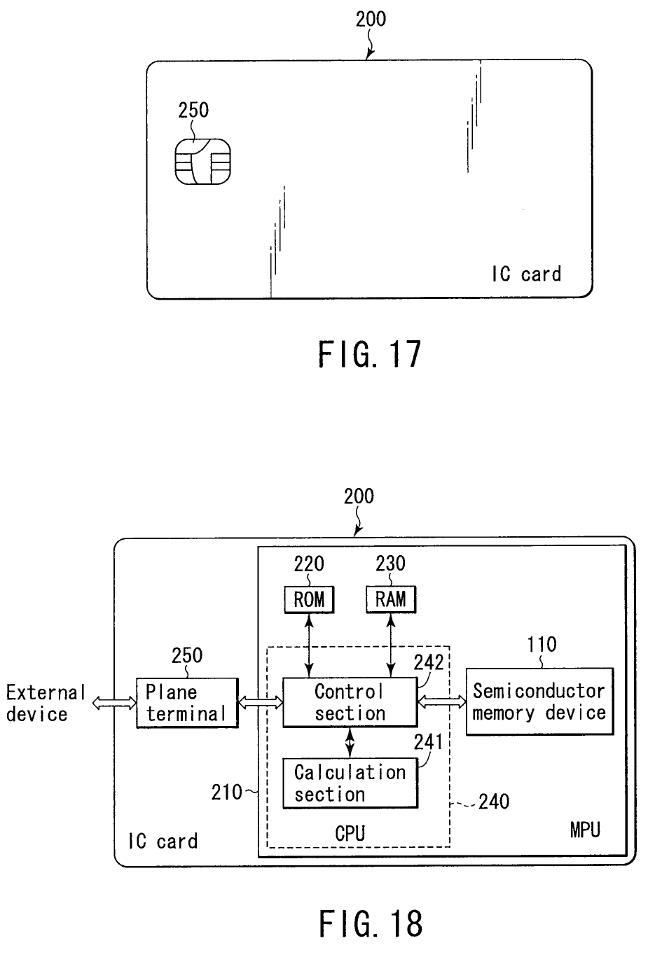

FIG. 17 and FIG. 18 show an IC card.

As illustrated in FIG. 17 and FIG. 18, an IC card 200 includes a MPU 210. The MPU 210 includes the non-volatile semiconductor memory device 110 according to one embodiment of the present invention or the modification example, and other circuits, that is, ROM 220, RAM 230 and CPU 240. The IC card 200 has a plane terminal 250 connectable to electronic apparatus. The plane terminal 250 is connected to the MPU 210. The CPU 240 includes a calculation section 241 and a control section 241. The control section 242 is connected to semiconductor memory device 110, ROM 220 RAM 230 and calculation section 241.

FIG. 19 shows a card holder.

As depicted in FIG. 19, the memory card 100 or IC card 200 is inserted into a card holder 130 so that it can be connected to electronic device (not shown). The card holder 130 may have part of functions of controller 120 and CPU 240.

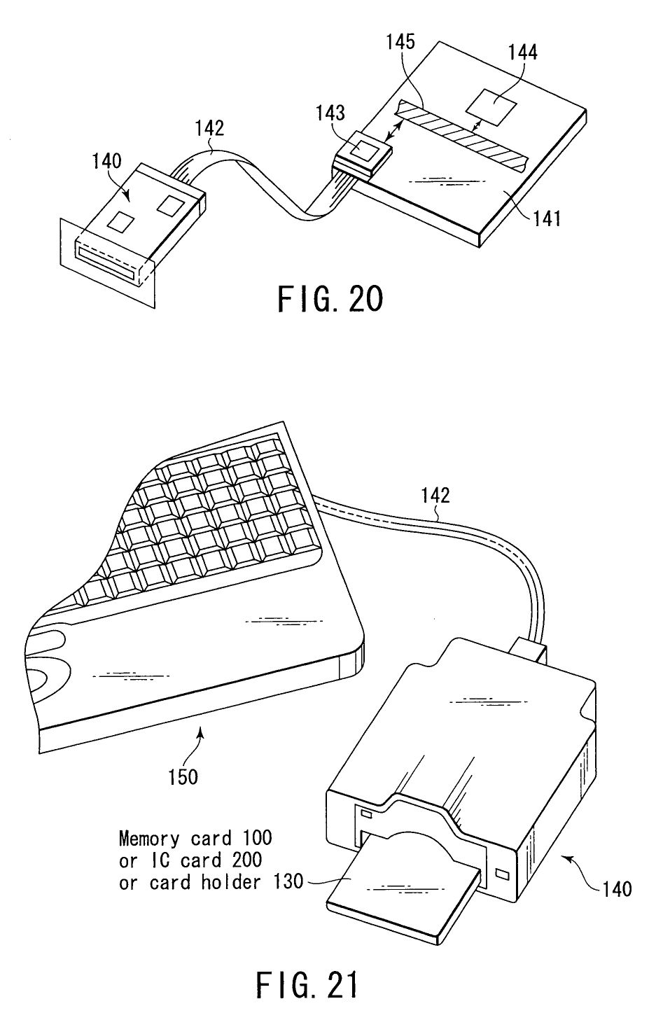

FIG. 20 shows an electronic device using the memory card 100, IC card 200 or card holder 130.

As illustrated in FIG. 20, memory card 100, IC card 200 or card holder 130 is inserted into a connector 140. The connector 140 is connected to a board 141 via connection cable 142 and interface circuit 143. The board 141 is mounted with CPU 144 and bus 145. The board 141 is applicable as a circuit board of computer, printer and portable (mobile) phone.

FIG. 21 shows another electronic device using the memory card 100 or card holder 130.

As seen from FIG. 21, the memory card 100 or card holder 130 into which the memory card 100 is inserted is inserted into a connector 140. The connector 140 is connected to an electronic device, for example, personal computer (PC) 150 via connection cable 142.

As described above, the memory card and IC card includes the non-volatile semiconductor memory device according to one embodiment of the present invention or the modification example. Therefore, the memory card and IC card using the non-volatile semiconductor memory device are applicable to various electronic devices.

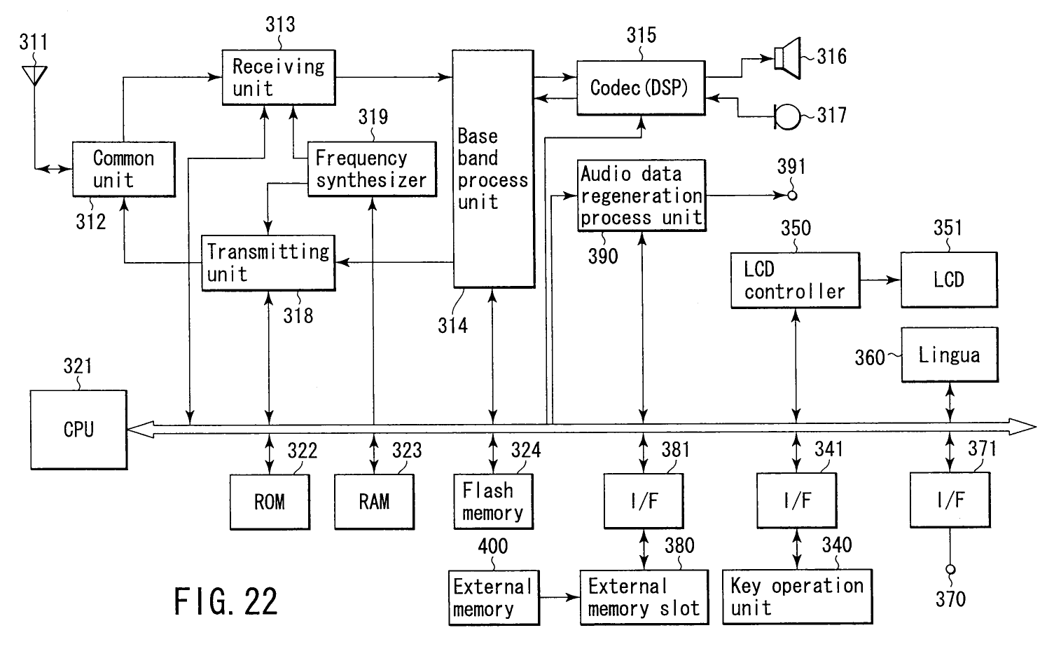

FIG. 22 shows a block example of a portable (mobile) phone terminal.

As shown in FIG. 22, a portable phone terminal includes a communication section and a control section.

The communication section includes transmitter-receiver antenna 311, antenna common unit 312, receiving unit 313, base band process unit 314, DSP 315, speaker 316, microphone 317, transmitting unit 318 and frequency synthesizer 319. The DSP (Digital Signal Processor) 315 is used as voice codec.

The control section includes CPU 321, and ROM 322, RAM 323 and flash memory 324, which are connected to the CPU 321 via CPU bus 330. The flash memory 324 is the non-volatile semiconductor memory device according to one embodiment of the present invention or the modification example. The ROM 322 stores programs executed by the CPU 321 and data necessary for display fonts. The RAM 323 is mainly used as a work area. For example, the RAM 323 stores calculating data as the need arises during program execution by the CPU 321, and temporarily stores data exchanged between the control section and units other than the control section. The flash memory 324 is a non-volatile semiconductor memory device; therefore, data stored in the portable phone terminal is not erased even if it is powered off. For this reason, the flash memory 324 stores previous setting conditions even if the portable phone terminal is powered off. In addition, the flash memory 324 stores setting parameters necessary for using the portable phone terminal under the same setting conditions in the next power-on.

The portable phone terminal according to the application example further includes key operation unit 340, LCD controller 350, lingua 360, external input/output terminal 370, external memory slot 380 and audio data regeneration process unit 390.

The key operation unit 340 is connected to the CPU bus 330 via an interface circuit (I/F) 341. Key input information inputted by the key operation unit 340 is sent to the CPU 321.

The LCD controller 350 receives display information from the CPU 321 via the CPU bus 330, and thereafter, converts it into LCD control information for controlling a LCD (liquid crystal display) 351 so that the information can be transmitted to the LCD 315.

The lingua 360 generates ring tone, for example.

The external input/output terminal 370 is connected to the CPU bus 330 via an interface circuit (I/F) 371. The external input/output terminal 370 functions as a terminal for inputting external information to the portable phone terminal or outputting it from there to the outside.

The external memory slot 380 insert an external memory 400 such as memory card therein. The external memory slot 380 is connected to the CPU bus 330 via an interface circuit (I/F) 381. The portable phone terminal 300 is provided with the slot 380, and thereby, the following advantages are given. Information from the portable phone terminal is written to the external memory 400, or information stored in the external memory 400 is read so that it can be inputted to the portable phone terminal. The foregoing memory card 100, card holder 130 and IC card 200 may be used as the external memory 400.

The audio data regeneration process unit 390 regenerates (reproduces, plays back) audio information inputted to the portable phone terminal or stored in the external memory 400. The regenerated audio information is transmitted to headphone and portable speaker via an external terminal 391, and thereby, fetched to the outside. The portable phone terminal is provided with the audio data regeneration process unit 390, and thereby, audio information can be regenerated.

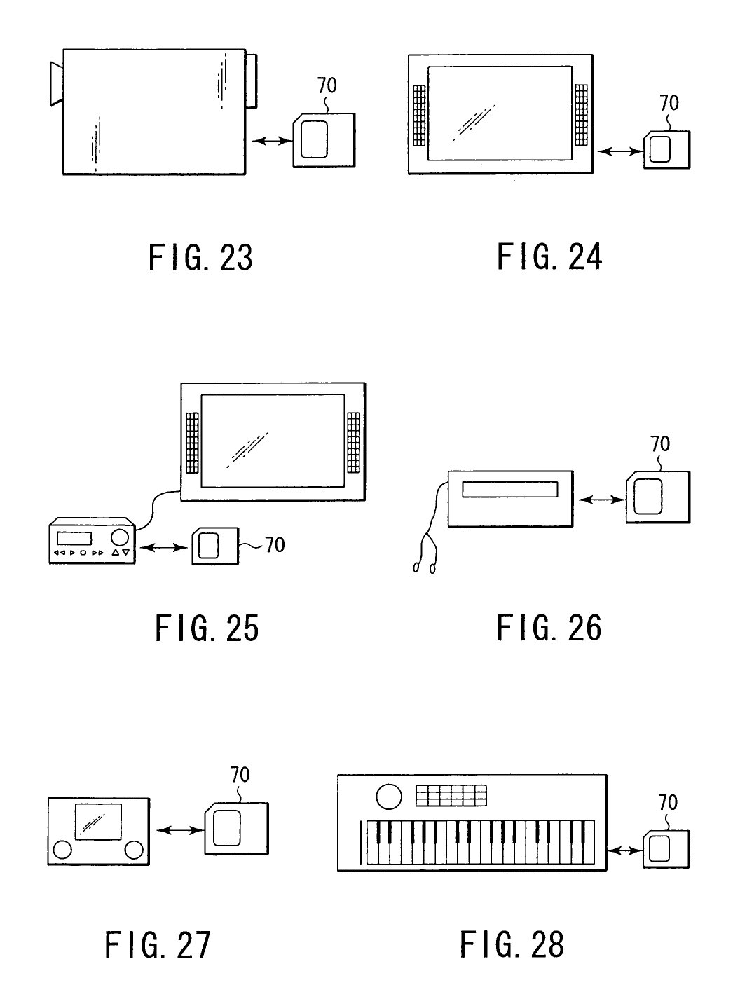

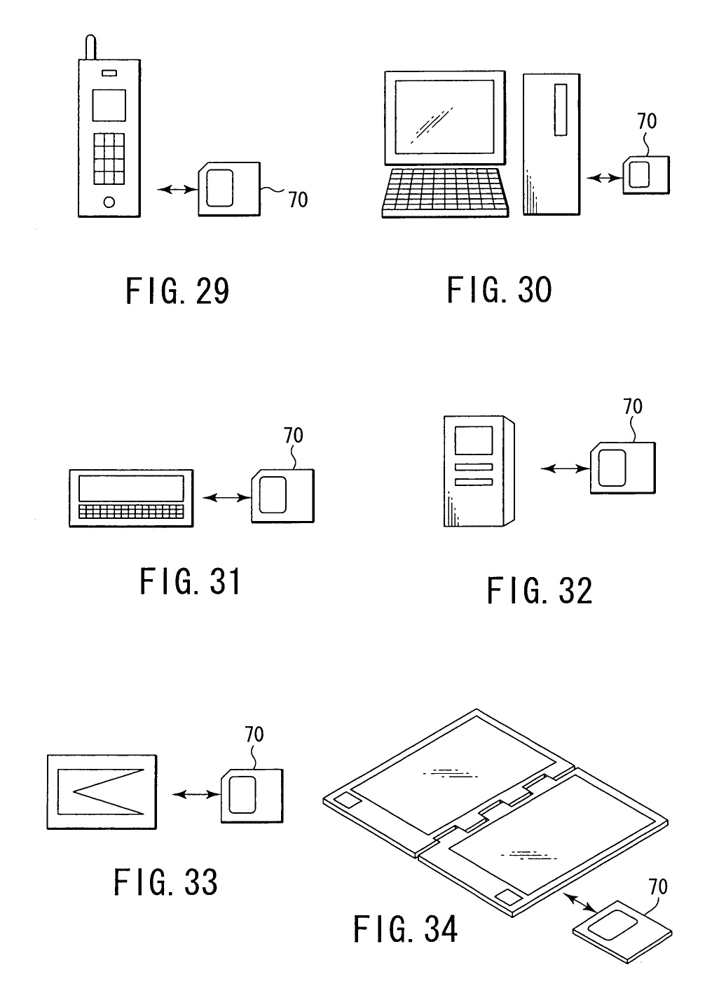

The memory card or IC card using the non-volatile semiconductor memory device according to one embodiment is applicable to various devices shown in FIG. 23 to FIG. 34. For example, the devices are digital still camera/video camera (FIG. 23), television (FIG. 24), audio/visual device (FIG. 25), audio device (FIG. 26), game machine (assistant) (FIG. 27) and electronic musical instrument (FIG. 28). Further, the devices are portable (mobile) phone (FIG. 29), personal computer (FIG. 30), personal digital assistant (PDA) (FIG. 31), voice recorder (FIG. 32), PC card (FIG. 33) and electronic book viewer (reader) (FIG. 34).

In addition, the memory card or IC card using the non-volatile semiconductor memory device according to one embodiment is applicable to IC tags.

One embodiment of the present invention has been explained above. The present invention is not limited to one embodiment, and various modifications are possible within the scope without departing from the spirit of the general inventive concept. For example, the non-volatile semiconductor memory having the floating gate is given as one example of the memory cell. In this case, memory cells other than above may be used. Of course, the foregoing one embodiment is not the solo embodiment.

One embodiment includes various inventive steps, and several constituent features disclosed in one embodiment are properly combined, thereby extracting various inventive steps.

The present embodiment has explained based on the case where the present invention is applied to the non-volatile semiconductor memory and the memory system using the same. The present invention is not limited to the non-volatile semiconductor memory and the memory system using the same. For example, the present invention is applicable to a semiconductor integrated circuit device including non-volatile semiconductor memory and memory system using the same, that is, processor, system LSI, etc.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. (canceled)

2. A method of manufacturing a memory system including a plurality of semiconductor memories each of which includes 2ⁿ+N (n, N: integer number) memory blocks, the method comprising:
allocating one of block addresses to each of the 2ⁿ+N memory blocks (where 2ⁿ>N), the memory blocks including a plurality of memory cells, the block addresses being non-continuous between the semiconductor memories; and
making a defective one of the memory blocks unusable without replacing the defective one of the memory blocks by another one of the memory blocks.

3. The method according to claim 2, wherein at least one of bits in each of the block addresses is a value unique to each of the semiconductor memories.

4. The method according to claim 2, wherein the block addresses in each of the semiconductor memories have at least one bit value in common, and
the semiconductor memories are different in said at least one bit value.

5. The method according to claim 2, wherein the block addresses have at least (n+M) bits,
first to (n+1)-th bits of the block addresses designate one of the memory blocks, and
at least (n+2)-th bit of the block addresses designate one of the semiconductor memories.

6. The method according to claim 5, wherein the memory system includes four semiconductor memories, and
(n+2)-th and (n+3)-th bits of the block addresses designate one of the semiconductor memories.

7. The method according to claim 2, wherein the block addresses are continuous in each of the semiconductor memories.

8. The method according to claim 2, wherein an address following a final block address of a first one of the semiconductor memories through an address preceding an initial address of a second one of the semiconductor memories are allocated to no memory blocks.

9. The method according to claim 2, wherein the memory blocks include:
memory cells including a floating gate and a control gate;
a NAND memory unit in which the memory cells are connected in series;
a bit line connected to one terminal of the NAND memory unit;
a source line connected to other terminal of the NAND memory unit; and
a plurality of word lines connected to the control gate of the memory cells.

10. A method of manufacturing a memory system including first and second semiconductor memories each of which includes 2ⁿ+N (where 2ⁿ>N, n and N are integer number) memory blocks, the method comprising:
allocating first block addresses to the memory blocks in the first semiconductor memory, the first block addresses being at least (n+2)-bits; and
allocating second block addresses to the memory blocks in the second semiconductor memory, the second block addresses being at least (n+2)-bits, a final address of the first block addresses and a initial address of the second block addresses being non-continuous.

11. The method according to claim 10, further comprising making a defective one of the memory blocks unusable without replacing the defective one of the memory blocks by another one of the memory blocks.

12. The method according to claim 10, wherein at least one of bits in each of the first block addresses is a value unique to the first semiconductor memory, and
at least one of bits in each of the second block addresses is a value unique to the second semiconductor memory.

13. The method according to claim 12, wherein said at least one of bits in each of the first block addresses is different from said at least one of bits in each of the second block addresses.

14. The method according to claim 10, wherein first to (n+1)-th bits of the first and second block addresses designate the memory blocks in the first and second semiconductor memories, respectively, and
at least (n+2)-th bit of the first and second block addresses designate the first and second semiconductor memories, respectively.

15. The method according to claim 10, wherein the first block addresses are continuous, and the second block addresses are continuous.

16. The method according to claim 10, wherein an address following a final address of the block addresses through an address preceding an initial address of the second block addresses are allocated to no memory blocks.

17. The method according to claim 10, wherein the memory blocks include:
memory cells including a floating gate and a control gate;
a NAND memory unit in which the memory cells are connected in series;
a bit line connected to one terminal of the NAND memory unit;
a source line connected to other terminal of the NAND memory unit; and
a plurality of word lines connected to the control gate of the memory cells.
